(19) United States
(12) Patent Application Publication
(10) Pub. No.: US 2026/0027611 A1
(43) Pub. Date: Jan. 29, 2026

(54) CREATING COMPLEX THREE-DIMENSIONAL WAX MODELS FOR INVESTMENT CASTING

(71) Applicant: International Business Machines Corporation, Armonk, NY (US)

(72) Inventors: Sarbajit Kumar Rakshit, Kolkata (IN); Sudheesh S. Kairali, Kozhikode (IN); Binoy Thomas, Kozhikode (IN)

(21) Appl. No.: 18/783,913

(22) Filed: Jul. 25, 2024

(51) Int. Cl. B22C 7/02; B33Y 50/00; B33Y 80/00; G06F 30/17

(52) U.S. Cl. CPC B22C 7/02; B33Y 50/00; B33Y 80/00; G06F 30/17

(57) ABSTRACT

Described are techniques for creating complex three-dimensional wax models for investment casting. A digital three-dimensional model of an object (e.g., transmission part, engine part, brake, bracket, housing, rod, gear, door handle, etc.) is analyzed. Segmented wax models to be formed from the digital three-dimensional model of the object are then identified. A production line using robots is then established for assembling the identified segmented wax models into a complete three-dimensional wax model of the object for investment casting. In this manner, complex three-dimensional wax models may be created for investment casting with less defects than creating such wax models using single injection molding.

### TECHNICAL FIELD

The present disclosure relates generally to investment casting.

### BACKGROUND

Investment casting, also known as precision casting or lost-wax casting, is a manufacturing process used to create complex and intricate metal parts with a high degree of accuracy and detail. Investment casting is known for its ability to produce parts with intricate details and fine surface finishes. It is often used in industries, such as aerospace, automotive, jewelry, and art casting, where high precision and quality are essential.

### SUMMARY

In one embodiment of the present disclosure, a computer-implemented method for creating complex three-dimensional wax models for investment casting comprises analyzing a digital three-dimensional model of an object. The method further comprises identifying segmented wax models to be formed from the digital three-dimensional model of the object. The method additionally comprises establishing a production line using robots for assembling the identified segmented wax models into a complete three-dimensional wax model of the object for the investment casting.

Other forms of the embodiment of the computer-implemented method described above are in a system and in a computer program product.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates an embodiment of the present disclosure of a communication system for practicing the principles of the present disclosure;

FIG. 2 illustrates the primary physical and logical components of a robot in accordance with an embodiment of the present invention;

FIG. 3 is a diagram of the software components used by the investment casting facilitator to create more complex, accurate three-dimensional wax models than previously created using single injection molding by segmenting a digital three-dimensional model of an object into segmented wax models in accordance with an embodiment of the present disclosure;

FIG. 4 illustrates populating a knowledge corpus with information regarding the different types of three-dimensional model specifications and the types of defects in the wax model in accordance with an embodiment of the present disclosure;

FIG. 5 illustrates an embodiment of the present disclosure of the hardware configuration of the investment casting facilitator which is representative of a hardware environment for practicing the present disclosure; and

FIGS. 6A-6B are a flowchart of a method for creating complex three-dimensional wax models for investment casting in accordance with an embodiment of the present disclosure.

### DETAILED DESCRIPTION

As stated above, investment casting, also known as precision casting or lost-wax casting, is a manufacturing process used to create complex and intricate metal parts with a high degree of accuracy and detail. Investment casting is known for its ability to produce parts with intricate details and fine surface finishes. It is often used in industries, such as aerospace, automotive, jewelry, and art casting, where high precision and quality are essential.

The process of investment casting includes various steps, such as pattern creation. A wax or similar material is used to create a pattern or replica of the desired part. This wax pattern or model is typically slightly oversized to account for shrinkage during the casting process. Next, multiple wax patterns are attached to a central wax gating system thereby creating a cluster of patterns that resemble a tree. This assembly is known as the “tree” or “sprue.” The wax tree is then coated with a ceramic material, which forms a hard shell around the patterns. This shell is called the “investment.” The investment is heated in an oven or autoclave, causing the wax to melt and run out, leaving behind a cavity in the shape of the desired part within the ceramic mold. The ceramic mold is fired at high temperatures to harden it and remove any remaining traces of wax. This creates a robust and heat-resistant mold. Molten metal, often aluminium, brass, bronze, or stainless steel, is then poured into the preheated mold. The metal fills the cavity and takes on the exact shape of the wax pattern. The metal cools and solidifies within the mold, forming the final part. Once the metal has solidified and cooled, the ceramic shell is broken and removed, revealing the cast metal part. The cast part may require additional machining, grinding, and other post-processing steps to achieve the desired surface finish and dimensional accuracy.

Investment casting offers several advantages, making it a preferred choice for manufacturing complex parts with high precision and intricate details. Some of the key advantages of investment casting include the ability to create parts with highly complex and intricate shapes, including internal cavities, thin walls, and fine details that are difficult to achieve using other manufacturing methods. Furthermore, the process offers excellent dimensional accuracy and tight tolerances, reducing the need for additional machining and finishing, which can save time and costs.

Other advantages of investment casting include the ability to product parts with a smooth and fine surface finish, reducing the need for extensive post-processing and achieving a high-quality appearance. Furthermore, the method minimizes material waste because only the exact amount of metal required for the part is used, and the wax patterns can be reused for multiple castings. Additionally, since investment casting produces parts with tight tolerances, less machining is usually needed, saving time and reducing material loss.

Unfortunately, the manufacturing of complex, large three-dimensional objects with a high-quality surface finish presents a challenge for investment casting when creating exact wax patterns or models. Such wax models are often created using single injection molding, which results in defects in the wax models.

The embodiments of the present disclosure provide a means for creating more complex, accurate three-dimensional wax models than previously created using single injection molding by segmenting a digital three-dimensional model of an object into segmented wax models. Such segmented wax models may then be assembled into a complete, complex, large three-dimensional wax model. In connection with identifying the segmented wax models to be formed from the digital three-dimensional model of the object as well as assembling the segmented wax models into the complete, complex, large three-dimensional wax model, a knowledge corpus as well an artificial intelligence model(s) are utilized to identify various facets to eliminate defects in the complete three-dimensional wax model. For example, such a knowledge corpus and artificial intelligence models identify the manufacturing process(es) to create the identified segmented wax models, calculate the tolerance limits for each segmented wax model, identify openings in the segmented wax models when assembled to enable air to escape during casting, predict air trap areas in the segmented wax models when assembled to determine positions and dimensions of the identified openings, identify excess material, if any, coming out when the segmented wax models are joined, identify an amount of surface finish and an amount of material removal/insertion in the segmented wax models when assembled, etc. A robotic system may then dynamically establish a production line with various combinations of manufacturing steps (e.g., wax cutting, 3D printing, polishing, assembly, quality evaluation, etc.) in order to assemble the segmented wax models in accordance with the information obtained from the knowledge corpus and artificial intelligence models. In this manner, complex three-dimensional wax models may be created for investment casting with less defects than creating such wax models using single injection molding. These and other features will be discussed in further detail below.

In some embodiments of the present disclosure, the present disclosure comprises a computer-implemented method, system, and computer program product for creating complex three-dimensional wax models for investment casting. In one embodiment of the present disclosure, a digital three-dimensional model of an object (e.g., transmission part, engine part, brake, bracket, housing, rod, gear, door handle, etc.) is analyzed. In one embodiment, the digital three-dimensional model of the object is analyzed by converting the digital three-dimensional model into a mesh model of granular sizes and dimensions, where the geometry and dimensions of the different portions of the three-dimensional object from the three-dimensional mesh model are identified. A mesh model, as used herein, is a collection of vertices, edges, and faces that together form a three-dimensional object. The vertices are the coordinates in three-dimensional space, the edges each connect two adjacent vertices, and the faces (also called polygons) enclose the edges to form the surface of the object. Segmented wax models to be formed from the digital three-dimensional model of the object are then identified. In one embodiment, the segmented wax models are identified based on breaking down the three-dimensional object into multiple sections using the learned geometry and dimensions of the three-dimensional object, which are compared with previous sections of objects for which segmented wax models have been formed as identified in a knowledge corpus. A production line using robots is then established for assembling the identified segmented wax models into a complete three-dimensional wax model of the object for investment casting. In one embodiment, the production line is dynamically established using robots for assembling segmented wax models into a complete three-dimensional wax model of the object for investment casting taking into consideration the manufacturing processes used to create the identified segmented wax models, tolerance limits for each segmented wax models, the determined positions and dimensions of identified openings, excess material, if any, identified as coming out when segmented wax models are joined, amount of surface finish and amount of material removal/insertion in the segmented wax models, etc. In this manner, complex three-dimensional wax models may be created for investment casting with less defects than creating such wax models using single injection molding.

In the following description, numerous specific details are set forth to provide a thorough understanding of the present disclosure. However, it will be apparent to those skilled in the art that the present disclosure may be practiced without such specific details. In other instances, well-known circuits have been shown in block diagram form in order not to obscure the present disclosure in unnecessary detail. For the most part, details considering timing considerations and the like have been omitted inasmuch as such details are not necessary to obtain a complete understanding of the present disclosure and are within the skills of persons of ordinary skill in the relevant art.

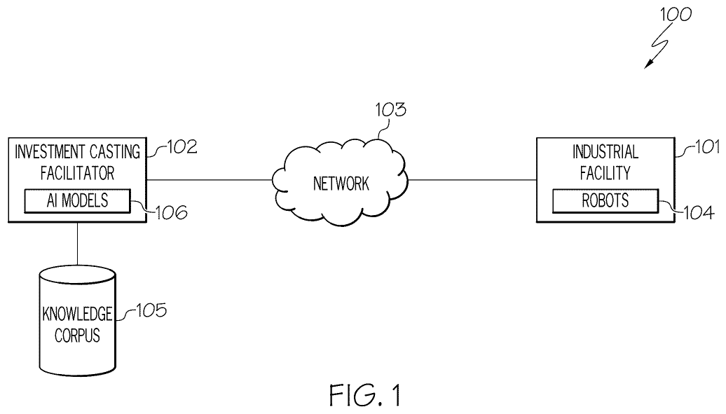

Referring now to the Figures in detail, FIG. 1 illustrates an embodiment of the present disclosure of a communication system 100 for practicing the principles of the present disclosure. Communication system 100 includes an industrial facility 101 connected to an investment casting facilitator 102 via a network 103.

An “industrial facility” 101, as used herein, refers to a complex (e.g., manufacturing plant) which may consist of one or more buildings that include an industrial floor infrastructure. An industrial floor infrastructure, as used herein, refers to the machines, devices, robots, etc. that operate on the industrial floor (floor, such as concrete, used in industrial and commercial settings, such as a plant) of industrial facility 101 to manufacture and produce parts, goods, pieces, etc. For example, such an industrial floor infrastructure may include robots 104 forming a production line for assembling the segmented wax models into a complete, complex, large three-dimensional wax model. In one embodiment, such robots 104 are dynamically utilized to form a production line for assembling the segmented wax models into a complete, complex, large three-dimensional wax model based on information obtained from a knowledge corpus, such as knowledge corpus 105 connected to investment casting facilitator 102, as well as one or more artificial intelligence (AI) models 106.

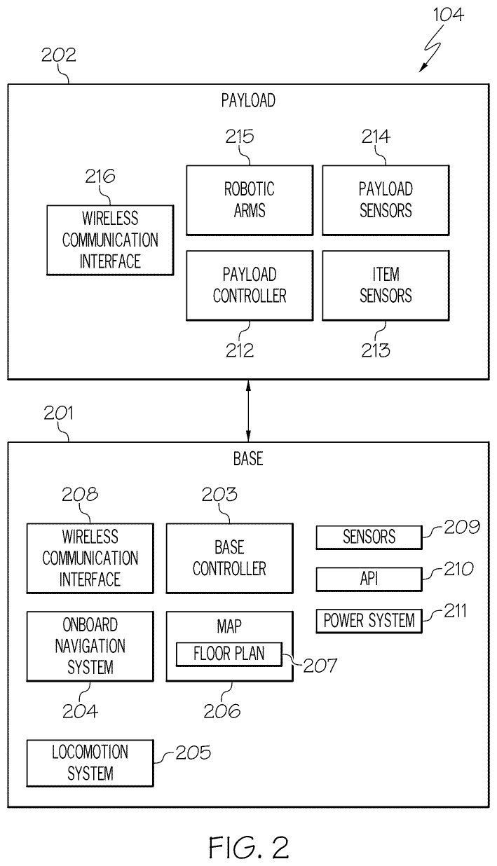

A “robot” 104 (also referred to as an industrial robot), as used herein, is a machine capable of carrying out a complex series of actions automatically, such as in the manufacturing process. In one embodiment, robots are automated, programmable, and capable of movement on three or more axes. Typical applications of robots include assembly, disassembly, pick and place, etc. in connection with assembling the segmented wax models into a complete, complex, large three-dimensional wax model. Examples of such robots 104 can include, but are not limited to, continuum robots (type of robot that is characterized by infinite degrees of freedom and number of joints), pneumatic robots (type of robots that receives locomotion from compressed air) and soft robots (constructed from delicate, flexible, and lifelike materials, which enable soft robots to more nimbly explore). A detailed description of the physical and logical components of robots 104 is provided below in connection with FIG. 2.

Referring again to FIG. 1, investment casting facilitator 102 is configured to create more complex, accurate three-dimensional wax models than previously created using single injection molding by segmenting a digital three-dimensional model of an object into segmented wax models. Such segmented wax models may then be assembled, such as by robots 104 as discussed above, into a complete, complex, large three-dimensional wax model.

In one embodiment, investment casting facilitator 102 identifies the segmented wax models from the digital three-dimensional model of the object as well as the shapes, sizes, form, etc. of such segmented wax models and how such segmented wax models are to be assembled, such as by robots 104, into a complete, complex, large three-dimensional wax model with less defects than wax models created from prior techniques (e.g., single injection molding) using knowledge corpus 105 as well an artificial intelligence model(s) 106. For example, knowledge corpus 105 and artificial intelligence model(s) 106 are used by investment casting facilitator 102 to identify the manufacturing process(es) to create the identified segmented wax models, calculate the tolerance limits for each segmented wax model, identify openings in the segmented wax models when assembled to enable air to escape during casting, predict air trap areas in the segmented wax models when assembled to determine positions and dimensions of the identified openings, identify excess material, if any, coming out when the segmented wax models are joined, identify an amount of surface finish and an amount of material removal/insertion in the segmented wax models when assembled, etc. Such knowledge is utilized by investment casting facilitator 102 to employ robots 104 to dynamically establish a production line with various combinations of manufacturing steps (e.g., wax cutting, 3D printing, polishing, assembly, quality evaluation, etc.) in order to assemble the segmented wax models in accordance with the information obtained from knowledge corpus 105 and artificial intelligence models 106.

Knowledge corpus 105, as used herein, refers to a collection of data that contains information pertaining to identifying segmented wax models to be formed from a digital three-dimensional model of an object (e.g., transmission part, engine part, brake, bracket, housing, rod, gear, door handle, etc.) as well as information pertaining to assembling such segmented wax models into a complete, complex, large three-dimensional wax model. For example, such data may include which objects that accurate wax models can be created using single injection modeling and which objects that wax models cannot accurately be created using single injection modeling, sections of objects for which segmented wax models have been formed, the types of shapes and dimensions of three-dimensional objects where investment casting-based manufacturing will be difficult, manufacturing methods used for various types of segmented wax models (e.g., 3D printing, wax cutting), required surface finishes for various types of segmented wax models, amount of material removal for various assembled segmented wax models, alterations to be implemented in various assembled segmented wax models based on required allowances, etc.

An artificial intelligence (AI) model 106, as used herein, refers to a program that has been trained on a set of data to recognize certain patterns or make certain decisions without further human intervention. Artificial intelligence models apply different algorithms to relevant data inputs to achieve the tasks, or output, they have been programmed for. That is, an AI model is defined by its ability to autonomously make decisions or predictions, rather than simulate human intelligence. Such decisions include the types of shapes and dimensions of the segmented wax models, manufacturing methods used for the segmented wax models (e.g., 3D printing, wax cutting), required surface finishes for the segmented wax models, amount of material removal for the assembled segmented wax models, alterations to be implemented in the assembled segmented wax models based on required allowances, calculating the necessary tolerance limits (e.g., tolerance limits for dimensions, surface roughness) for each individual segmented wax model, identifying the portions of the completed assembled wax model that are to be expanded into two or more separate sections which allow for the creation of two or more openings in the mold, predicting where air might become trapped within the mold to determine positions and dimensions of openings (openings identified to enable air to escape during casting) required in the molds for complete wax model creation, identifying sections of assembled wax models to create multiple mold openings to enable air to escape during casting, identifying excess material, if any, coming out when segmented wax models are joined, etc.

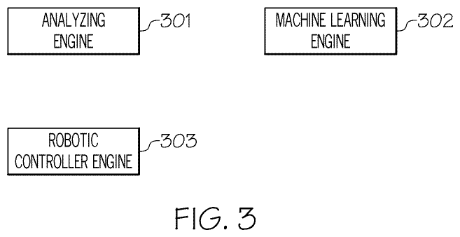

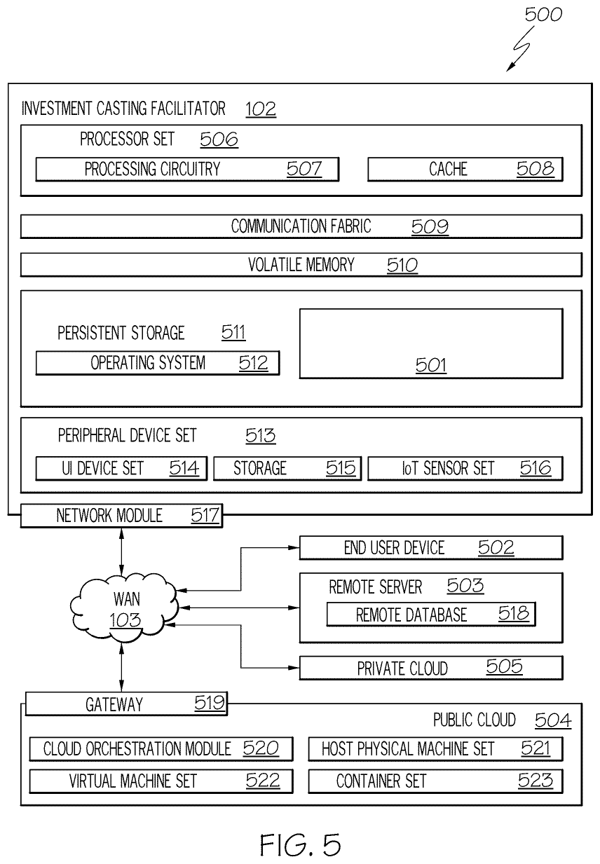

A description of the software components of investment casting facilitator 102 used for creating more complex, accurate three-dimensional wax models than previously created using single injection molding by segmenting a digital three-dimensional model of an object into segmented wax models is provided below in connection with FIG. 3. A description of the hardware configuration of investment casting facilitator 102 is provided further below in connection with FIG. 5.

Network 103 may be, for example, a local area network, a wide area network, a wireless wide area network, a circuit-switched telephone network, a Global System for Mobile Communications (GSM) network, a Wireless Application Protocol (WAP) network, a WiFi network, an IEEE 802.11 standards network, various combinations thereof, etc. Other networks, whose descriptions are omitted here for brevity, may also be used in conjunction with system 100 of FIG. 1 without departing from the scope of the present disclosure.

System 100 is not to be limited in scope to any one particular network architecture. System 100 may include any number of industrial facilities 101, investment casting facilitators 102, networks 103, robots 104, knowledge corpuses 105, and AI models 106.

Referring now to FIG. 2, FIG. 2 illustrates the primary physical and logical components of robot 104 in accordance with an embodiment of the present invention.

As shown in FIG. 2, robot 104 includes a base 201 and a payload 202. In one embodiment, base 201 includes a variety of hardware and software components, including a base controller 203, an onboard navigation system 204, a locomotion system 205, a map 206 defining a floor plan 207, such as the floor plan of industrial facility 101, a wireless communication interface 208, sensors 209, an application programming interface (API) 210 and a power system 211.

In one embodiment, base controller 203 includes computer program instructions executable on a microprocessor (not shown) to initiate, coordinate, and manage all of the automation functions associated with robot 104, including without limitation, handling of job assignments, automatic locomotion and navigation, communications with other computers and other robots 104, activating the payload functions, and controlling power functions. In one embodiment, base controller 203 has an assignment manager (not shown) that keeps track of all of the robot's assignments and job operations. When a job assignment is received by robot 104, base controller 203 activates the other subsystems in robot 104 to respond to the job assignment. Thus, base controller 203 generates and distributes the appropriate command signals that cause other processing modules and units on robot 104 to start carrying out the requested job assignment (e.g., assembling segmented wax models). So, for example, when the received job assignment requires that robot 104 drive itself to a certain part chamber (e.g., part chamber that contains a designated segmented wax model) at a certain location in the physical environment, it is base controller 203 that generates the command signal that causes onboard navigation system 204 to start driving robot 104 to the specified destination. Base controller 203 also provides an activation signal for payload 202, if necessary, to cause payload 202 to perform a particular operation (e.g., pick designated segmented wax model from designated part chamber) at the specified job location. Base controller 203 also manages and updates map 206, and floor plan 207, when appropriate, based on updated map or floor plan information received from investment casting facilitator 102 or other robots 104 in the computer network. Base controller 203 also receives assignment status information, if any, from payload 202 and, if appropriate, relays the status information out to investment casting facilitator 102, which typically delegates job assignments to robots 104. Typically, base controller 203 will communicate with investment casting facilitator 102 via application programming interface (API) 210 and wireless communications interface 208.

In one embodiment, map 206 defines floor plan 207 comprised of an array of part chambers corresponding to the physical environment, such as industrial facility 101, and also defines a set of job locations in terms of floor plan 207. In one embodiment, map 206 also associates one or more job operations with one or more of the job locations in the set of job locations. In one embodiment, each job location on floor plan 207 corresponds to an actual location in the physical environment, such as industrial facility 101. Some of the job locations on floor plan 207 will also have associated with them a set of one or more job operations to be carried out automatically by robot 104 after robot 104 arrives at the actual location. In one embodiment, map 206 may be obtained by base controller 203 from investment casting facilitator 102 or from another robot 104 or from a standalone operating terminal for the network (not shown). Certain job operations on floor plan 207 may have multiple locations in the physical environment, such as industrial facility 101. It is understood, however, that not all job operations need to be pre-programmed into map 206. It is also possible for job operations to be commanded as needed by base controller 203, or investment casting facilitator 102, irrespective of whether or not the job operation is defined in map 206.

In one embodiment, onboard navigation system 204, operating under the control of base controller 203, handles all of the localization, path planning, path following and obstacle avoidance functions for robot 104. If the system includes a positive and negative obstacle avoidance engine to help robot 104 avoid colliding with objects that may be resting on the floor but whose shape is not appropriately identified by the robot's horizontally scanning laser, and to avoid driving into gaps in the floor, this functionality is encompassed by onboard navigation system 204. In one embodiment, onboard navigation system 204 automatically determines the job location for the job assignment based on the map and the job assignment. Using sensors 209, onboard navigation system 204 also detects when driving robot 104 along a selected path (movement path) from the robot's current position to an actual location in the physical environment will cause robot 104 to touch, collide or otherwise come too close to one or more of the stationary or non-stationary obstacles in the physical environment. When onboard navigation system 204 determines that contact with an obstacle might occur, it is able to automatically plan a path around the obstacle and return to the movement path as established by investment casting facilitator 102. In one embodiment, onboard navigation system 204 may also use sensing lasers to sample objects in the physical environment, and compare the samples with information in map 206. This process is called “laser localization.” Another known technique, called light localization, involves using a camera to find lights in the ceiling and then comparing the lights found to lights identified on map 206. All of these different techniques may be employed to help onboard navigation system 204 determine its current position relative to the job location.

In one embodiment, onboard navigation system 204 operates in combination with locomotion system 205 to drive robot 104 from its current location to the source or target location along the established movement path.

In one embodiment, API 210 is operatable with base controller 203 and wireless communication interface 208 to provide information and commands to base controller 203 as well as retrieve job assignment status and route information from base controller 203. For example, if payload 202 needs to send information concerning the status of the item being transported, such information may be transmitted from payload controller 212 to base controller 203 via API 210. Base controller 203 will then transmit such information to investment casting facilitator 102 through the same API 210. In one embodiment, API 210 is ARCL or ArInterface, an application programming interface distributed by Omron Adept Technologies, Inc. of San Ramon, California.

Sensors 209 may include a collection of different sensors, such as sonar sensors, bumpers, cameras, gas sensors, smoke sensors, motion sensors, etc., and can be used to perform a variety of different functions. These sensors may also be used for traffic mitigation by redirecting robot 104 when other robots 104 are detected in the immediate surroundings. Other elements on base 201 include power system 211, which typically includes a battery and software to manage the battery.

In one embodiment, locomotion system 205 includes the hardware and electronics necessary for making robot 104 move including, for example, motors, wheels, feedback mechanisms for the motors and wheels, and encoders. In one embodiment, onboard navigation system 204 “drives” robot 104 by sending commands down to the wheels and motors through locomotion system 205.

Referring now to the components of payload 202, item sensors 213 provide signals to payload controller 212 and, possibly, directly to base controller 203 by means of API 210, which permit payload controller 212 and/or base controller 203 to make programmatic decisions about whether robot 104 has completed an assignment or is available for more assignments.

In one embodiment, payload sensors 214 may include, for example, temperature or gas sensors, cameras, RFID readers, environmental sensors, wireless Ethernet sniffing sensors, etc. In one embodiment, payload sensors 214 may be used to provide information about the state of payload 202, the state of the physical environment, the proximity of robot 104 to physical objects, including other robots 104, or some combination of all of this information.

In one embodiment, payload 202 includes robotic arms 215 configured to pick segmented wax models from part chambers in an array of part chambers forming the assembling floor of industrial facility 101. A “robotic arm 215,” as used herein, is a type of mechanical arm that is programmable with similar functions to a human arm. In one embodiment, robotic arms 215 are programmed via commands received by base controller 203 and/or payload controller 212 via industrial casting facilitator 102. Furthermore, in one embodiment, with the use of robotic arm 215, robot 104 is able to assemble two or more segmented wax models into a larger wax model, including a complete, complex, large three-dimensional wax model of an object.

In one embodiment, payload 202 may also include a wireless communications interface 216, which sends information to and receives information from other devices or networks, such as from investment casting facilitator 102.

In one embodiment, payload controller 212 processes command and operation signals coming into payload 202 and generally controls and coordinates all of the functions performed by payload 202.

A discussion regarding the software components used by investment casting facilitator 102 to create more complex, accurate three-dimensional wax models than previously created using single injection molding by segmenting a digital three-dimensional model of an object into segmented wax models is provided below in connection with FIG. 3.

FIG. 3 is a diagram of the software components used by investment casting facilitator 102 to create more complex, accurate three-dimensional wax models than previously created using single injection molding by segmenting a digital three-dimensional model of an object into segmented wax models in accordance with an embodiment of the present disclosure.

Referring to FIG. 3, in conjunction with FIG. 1, investment casting facilitator 102 includes analyzing engine 301 configured to receive a digital three-dimensional model of an object (e.g., transmission part, engine part, brake, bracket, housing, rod, gear, door handle, etc.). In one embodiment, the received digital three-dimensional model of an object is associated with an identifier (e.g., name of object), which identifies the object.

In one embodiment, analyzing engine 301 analyzes knowledge corpus 105 pertaining to three-dimensional objects for which the creation of wax models for investment casting using single injection modeling is difficult. In one embodiment, knowledge corpus 105 is populated with a listing of three-dimensional objects for which the creation of wax models for investment casting using single injection modeling is difficult. In one embodiment, knowledge corpus 105 is populated by an expert.

In one embodiment, analyzing engine 301 determines if the creation of wax models for investment casting using single injection modeling is difficult for the object (e.g., brake pad) of the received digital three-dimensional model based on matching the identifier of the object with a listing of three-dimensional objects for which the creation of wax models for investment casting using single injection modeling is difficult.

Upon receipt of the digital three-dimensional model of an object, analyzing engine 301 determines whether there is a need to segment the digital three-dimensional model to form a wax model based on the analysis of knowledge corpus 105. A segment, as used herein, refers to a portion or section. By segmenting the digital three-dimensional model, multiple segmented wax models are formed from the digital three-dimensional model of the object. A segmented wax model, as used herein, refers to a wax model of a portion or section of the object. In one embodiment, such segmented wax models may be assembled into a complete three-dimensional wax model of the object for investment casting with fewer defects than previously created using single injection molding as discussed below.

In one embodiment, analyzing engine 301 determines whether there is a need to segment the received digital three-dimensional model to form a wax model based on the analysis of knowledge corpus 105 which involves determining if the creation of wax models for investment casting using single injection modeling is difficult for such an object (e.g., brake pad).

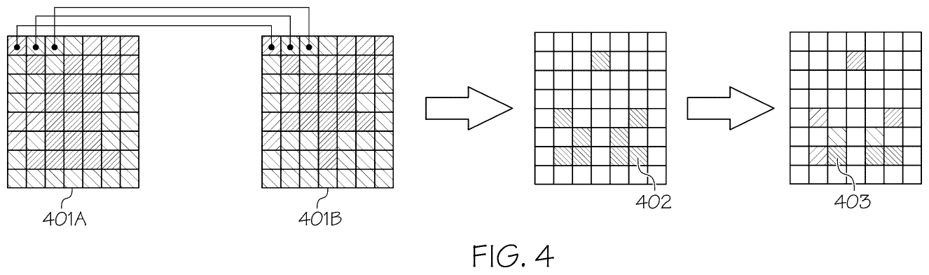

In one embodiment, knowledge corpus 105 contains information regarding the different types of three-dimensional model specifications and the types of defects in the wax model as illustrated in FIG. 4.

FIG. 4 illustrates populating knowledge corpus 105 with information regarding the different types of three-dimensional model specifications and the types of defects in the wax model in accordance with an embodiment of the present disclosure.

As shown in FIG. 4, a comparison is made between mesh model 401A of the three-dimensional model of the object and mesh model 401B of the wax model formed when created using single injection molding. In one embodiment, mesh models 401A, 401B are point cloud representations. As a result, in one embodiment, such a comparison corresponds to a point cloud comparison. A point cloud representation, as used herein, is a set of data points in a three-dimensional (3D) coordinate system (e.g., X, Y, and Z axes). A point cloud comparison, as used herein, refers to comparing the point cloud representations, such as the point cloud representations of mesh models 401A, 401B, to detect any changes which correspond to defects as discussed below.

Mesh models 401A-401B may collectively or individually be referred to as mesh models 401 or mesh model 401, respectively. In one embodiment, analyzing engine 301 creates such mesh models 401 using various software tools, which can include, but are not limited to, Blender, Autodesk Maya, 3ds Max®, etc.

Mesh model 401 is a collection of vertices, edges, and faces that together form a three-dimensional object. The vertices are the coordinates in three-dimensional space, the edges each connect two adjacent vertices, and the faces (also called polygons) enclose the edges to form the surface of the object.

In one embodiment, analyzing engine 301 detects defects 402 in the mesh model 401B of the wax model formed when created using single injection molding when there is a deviation between mesh models 401A, 401B, such as changes detected between the point cloud representations of mesh models 401A, 401B.

Manual annotation (see 403) may be utilized to highlight the defects with the wax models, where such defects are classified based on the types of defects.

Such information will be stored in knowledge corpus 105 and utilized to identify how different shapes, dimensions, etc. of the segmented wax models can avoid problems when assembled into the complete, complex, large three-dimensional wax model. In one embodiment, such information may be utilized by AI model 106, as discussed further below, to avoid problems when segmented wax models are assembled into the complete, complex, large three-dimensional wax model.

Returning to FIG. 3, in conjunction with FIGS. 1 and 4, based on such information in knowledge corpus 105, analyzing engine 301 determines whether there is a need to segment the received digital three-dimensional model of the object to form a wax model based on the analysis of knowledge corpus 105 which involves determining if the creation of wax models for investment casting using single injection modeling is difficult for such an object (e.g., brake pad). Such difficulty is determined based on defects, such as defects 402 of FIG. 4 that were detected.

If there is no difficulty in creating a wax model for investment casting using single injection molding for such an object as determined from knowledge corpus 105, then a wax model for investment casting will be created for such an object using single injection molding. Analyzing engine 301 will then proceed to wait to receive the next digital three-dimensional model of an object.

If, however, there is difficulty in creating a wax model for investment casting using single injection molding for such an object as determined from knowledge corpus 105, then analyzing engine 301 proceeds with identifying the segmented wax models to be formed from the digital three-dimensional model of the object.

In one embodiment, analyzing engine 301 analyzes the received digital three-dimensional model of an object (e.g., transmission part, engine part, brake, bracket, housing, rod, gear, door handle, etc.).

In one embodiment, analyzing engine 301 analyzes the digital three-dimensional model of the object by converting the digital three-dimensional model into a mesh model of granular sizes and dimensions. A mesh model, as used herein, is a collection of vertices, edges, and faces that together form a three-dimensional object. The vertices are the coordinates in three-dimensional space, the edges each connect two adjacent vertices, and the faces (also called polygons) enclose the edges to form the surface of the object.

In one embodiment, analyzing engine 301 creates a mesh model, such as a three-dimensional mesh model, from the digital three-dimensional model of the object using various software tools, which can include, but are not limited to, Blender, Autodesk Maya, 3ds Max®, etc.

In one embodiment, analyzing engine 301 creates a mesh model, such as a three-dimensional mesh model, from the object itself by utilizing three-dimensional scanning, which is a technique for converting a physical object into a three-dimensional mesh model. In one embodiment, a three-dimensional scanner is used to capture the surface of the object and create a digital mesh model.

In one embodiment, analyzing engine 301 identifies the geometry and dimensions of the different portions of the three-dimensional object from the three-dimensional mesh model. Analyzing engine 301 uses various software tools for such an analysis, which can include, but are not limited to, MeshInspector, 3ds Max®, MeshLab, etc.

In one embodiment, analyzing engine 301 identifies the segmented wax models to be formed from the digital three-dimensional model of the object.

In one embodiment, the segmented wax models are identified based on breaking down the three-dimensional object into multiple sections using the learned geometry and dimensions of the three-dimensional object, which are compared with previous sections of objects for which segmented wax models have been formed as identified in knowledge corpus 105.

As discussed above, knowledge corpus 105, as used herein, refers to a collection of data that contains information pertaining to identifying segmented wax models to be formed from a digital three-dimensional model of an object (e.g., transmission part, engine part, brake, bracket, housing, rod, gear, door handle, etc.) as well as information pertaining to assembling such segmented wax models into a complete, complex, large three-dimensional wax model. For example, such data may include which objects that accurate wax models can be created using single injection modeling and which objects that wax models cannot accurately be created using single injection modeling, sections of objects for which segmented wax models have been formed, the types of shapes and dimensions of three-dimensional objects where investment casting-based manufacturing will be difficult, manufacturing methods used for various types of segmented wax models (e.g., 3D printing, wax cutting), required surface finishes for various types of segmented wax models, amount of material removal for various assembled segmented wax models, alterations to be implemented in various assembled segmented wax models based on required allowances, etc.

In one embodiment, based on identifying sections of the three-dimensional object (e.g., brake pad) that have previously been segmented into segmented wax models from knowledge corpus 105, analyzing engine 301 proceeds with logically segmenting the digital three-dimensional model of the object. In one embodiment, analyzing engine 301 creates separate three-dimensional models or files for each segmented part preserving their alignment and assembly points. Analyzing engine 301 uses various software tools for creating separate three-dimensional models or files for each segmented part preserving their alignment and assembly points, which can include, but are not limited to, Alias®, Rhino, Blender®, etc.

In one embodiment, properties (e.g., geometry, dimensions, etc.) of such segmented wax models are obtained by analyzing engine 301, such as from the software tools used for creating separate three-dimensional models or files for each segmented wax model.

In one embodiment, once the digital three-dimensional model of the object is segmented, analyzing engine 301 allocates a sequence number to each segmented wax model in order of assembling thereby being able to assemble the segmented wax models into a complete three-dimensional wax model of the object for investment casting.

In connection with assembling the segmented wax models, analyzing engine 301 identifies the manufacturing processes to create the identified segmented wax models.

In one embodiment, such manufacturing processes may be identified from knowledge corpus 105 or using AI model 106. As discussed above, in one embodiment, knowledge corpus 105 includes information pertaining to manufacturing methods used for various types of segmented wax models (e.g., 3D printing, wax cutting). Based on identifying the types of segmented wax models to be used (obtained from identifying the segmented wax models to be formed from the three-dimensional model of the object), such information may be utilized by analyzing engine 301 to identify the manufacturing processes to create the identified segmented wax models.

As also discussed above, AI model 106 refers to a program that has been trained on a set of data to recognize certain patterns or make certain decisions without further human intervention. Artificial intelligence models apply different algorithms to relevant data inputs to achieve the tasks, or output, they have been programmed for. That is, an AI model is defined by its ability to autonomously make decisions or predictions, rather than simulate human intelligence. Such decisions include the types of shapes and dimensions of the segmented wax models, manufacturing methods used for the segmented wax models (e.g., 3D printing, wax cutting), required surface finishes for the segmented wax models, amount of material removal for the assembled segmented wax models, alterations to be implemented in the assembled segmented wax models based on required allowances, calculating the necessary tolerance limits (e.g., tolerance limits for dimensions, surface roughness) for each individual segmented wax model, identifying the portions of the completed assembled wax model that are to be expanded into two or more separate sections which allow for the creation of two or more openings in the mold, predicting where air might become trapped within the mold to determine positions and dimensions of openings (openings identified to enable air to escape during casting) required in the molds for complete wax model creation, identifying sections of assembled wax models to create multiple mold openings to enable air to escape during casting, identifying excess material, if any, coming out when segmented wax models are joined, etc.

Referring again to FIG. 3, investment casting facilitator 102 includes machine learning engine 302, which builds and trains an artificial intelligence model to make decision or predictions, such as the types of shapes and dimensions of the segmented wax models, manufacturing methods used for the segmented wax models (e.g., 3D printing, wax cutting), required surface finishes for the segmented wax models, amount of material removal for the assembled segmented wax models, alterations to be implemented in the assembled segmented wax models based on required allowances, calculating the necessary tolerance limits (e.g., tolerance limits for dimensions, surface roughness) for each individual segmented wax model, identifying the portions of the completed assembled wax model that are to be expanded into two or more separate sections which allow for the creation of two or more openings in the mold, predicting where air might become trapped within the mold to determine positions and dimensions of openings required in the molds for complete wax model creation, identifying sections of assembled wax models to create multiple mold openings to enable air to escape during casting, etc. Such decisions or predictions are based on a sample data set that includes the types of shapes and dimensions of the segmented wax models, manufacturing methods used for the segmented wax models (e.g., 3D printing, wax cutting), required surface finishes for the segmented wax models, amount of material removal for the assembled segmented wax models, alterations to be implemented in the assembled segmented wax models based on required allowances, the calculated necessary tolerance limits (e.g., tolerance limits for dimensions, surface roughness) for each individual segmented wax model, the portions of the completed assembled wax model that are to be expanded into two or more separate sections which allow for the creation of two or more openings in the mold, the predicted locations where air might become trapped within the mold to determine positions and dimensions of openings required in the molds for complete wax model creation, the sections of assembled wax models used to create multiple mold openings to enable air to escape during casting, etc. based on the properties of objects (e.g., geometry and dimensions of the different portions of the three-dimensional objects) and based on the properties (e.g., geometry, dimensions, etc.) of the identified segmented wax models.

In one embodiment, the sample data set discussed above may be stored in a data structure (e.g., table) residing within the storage device of investment casting facilitator 102. In one embodiment, such a data structure is populated by an expert.

Furthermore, in one embodiment, the sample data set discussed above is referred to herein as the “training data,” which is used by a machine learning algorithm to make predictions or decisions as discussed above. The algorithm iteratively makes predictions on the training data until the predictions achieve the desired accuracy as determined by an expert. Examples of such learning algorithms include nearest neighbor, Naïve Bayes, decision trees, linear regression, support vector machines, and neural networks.

Upon training artificial intelligence model 106 to make decision or predictions as discussed above based on the properties of objects (e.g., geometry and dimensions of the different portions of the three-dimensional objects) and based on the properties (e.g., geometry, dimensions, etc.) of the identified segmented wax models, the trained artificial intelligence model 106 generates such predictions for the object in question based on the properties of the object (e.g., geometry and dimensions of the different portions of the three-dimensional object) obtained from analyzing engine 301, such as based on analyzing the digital three-dimensional model of the object, as well as based on the properties of identified segmented wax models, which may be obtained from analyzing engine 301.

In one embodiment, AI model 106 generates manufacturing process(es) to create the identified segmented wax models based on the properties of the object and based on the properties of the identified segmented wax models.

Examples of such manufacturing processes can include, but are not limited to, wax injection modeling, wax 3D printing, CNC (computer numerical control) machining, polishing, assembling, quality evaluation, wax cutting, dipping on ceramic slurry, etc. to create wax patterns for each segmented part.

In one embodiment, such manufacturing processes ensure that the dimension and surface finish of each wax model meets the requirements for investment casting.

Returning again to FIG. 3, analyzing engine 301 calculates the tolerance limits for each segmented wax model. A tolerance limit, as used herein, is a measure used to ensure the uniformity or quality of the segmented wax model.

As discussed above, AI model 106 is trained to output the necessary tolerance limits for each segmented wax model to ensure accurate assembly and high-quality investment casting based on the properties of the object and the properties of the identified segmented wax models. In one embodiment, such an assessment performed by AI model 106 includes assessing factors, such as the manufacturing method's inherent accuracy, material properties, and the surface finish requirements.

Furthermore, prior to assembling the segmented wax models, analyzing engine 301 identifies the openings in the segmented wax models when they are assembled to enable air to escape during casting.

As discussed above, AI model 106 is trained to output the openings in the segmented wax models when they are assembled to enable air to escape during casting based on the properties of the object and the properties of the identified segmented wax models. For example, AI model 106 identifies the sections of the assembled wax models to create multiple mold openings to enable air to escape during casting based on the properties of the object and the properties of the identified segmented wax models. In one embodiment, such an assessment performed by AI model 106 includes ensuring that the expansion (completed assembled wax model is expanded into two or more separate sections) creates openings or channels in the model, which serve as pathways for air to escape during casting.

Furthermore, in one embodiment, analyzing engine 301 predicts air trap areas in the segmented wax models when they are assembled to determine positions and dimensions of the identified openings.

In one embodiment, analyzing engine 301 predicts air trap areas based on performing fluid dynamics simulations of the segmented wax models when they are assembled. Examples of software tools for implementing fluid dynamics simulations can include, but are not limited to, OpenFOAM®, Ansys® CFD simulation software, Autodesk® CFD software, etc.

As discussed above, AI model 106 is trained to predict where air might become trapped within the mold to determine the positions and dimensions of the openings (openings identified to enable air to escape during casting) required in the molds for complete wax model creation based on the properties of the object and the properties of the identified segmented wax models. In one embodiment, AI model 106 is trained, such as by machine learning engine 302, to recognize regions within the 3D model that are likely to lead to air trapping during the investment casting process. These could be areas with enclosed or hard-to-fill cavities. Furthermore, in one embodiment, AI model 106 is trained to expand the wax model, in two or more sides, so that the air trapped inside the mold can be released and aligned with the openings designed for air to escape.

Additionally, in one embodiment, analyzing engine 301 identifies excess material, if any, coming out when the segmented wax models are joined.

As discussed above, AI model 106 is trained to predict any excess material coming out when segmented wax models are joined based on the properties of the object and the properties of the identified segmented wax models.

In situations in which excess material is predicted to come out when segmented wax models are joined, robots 104 will be employed to heat the surfaces of the segmented wax models prior to assembly. In one embodiment, such heating involves infrared or induction heating. Robots 104 may then apply controlled pressure to securely join the segmented wax models ensuring that excess wax does not escape.

In one embodiment, in the event that excess wax escapes from the assembled portion of the segmented wax models, robots 104 may be employed to perform polishing to remove such excess wax thereby enabling the assembled segmented wax models to be utilized in forming the complete three-dimensional wax model of the object for investment casting.

Furthermore, in one embodiment, analyzing engine 301 identifies an amount of surface finish and an amount of material removal/insertion in the segmented wax models when assembled.

As discussed above, AI model 106 is trained to predict an amount of surface finish and an amount of material removal/insertion in the segmented wax models when assembled based on the properties of the object and the properties of the identified segmented wax models.

Furthermore, as discussed above, analyzing engine 301 identifies the amount of surface finish and an amount of material removal/insertion in the segmented wax models when assembled from knowledge corpus 105. For example, based on the properties (e.g., type of segmented wax model) of the identified segmented wax models, the amount of surface finish may be obtained from knowledge corpus 105, which stores the required surface finish for various types of segmented wax models. Furthermore, based on the properties (e.g., type of segmented wax model) of the segmented wax models, the amount of material removal/insertion in the segmented wax models when assembled may be obtained from knowledge corpus 105, which stores the amount of material removal for various assembled segmented wax models as well as alterations to be implemented in various assembled segmented wax models based on the required allowances (i.e., tolerances).

In one embodiment, knowledge corpus 105 stores the desired surface finish specification for the investment casting process based on the surface roughness, dimensional tolerances, and other quality requirements. Hence, analyzing engine 301, based on the surface roughness, dimensional tolerances, and other quality requirements of the segmented wax models, is able to identify the desired surface finish specification from knowledge corpus 105.

In one embodiment, knowledge corpus 105 and AI model 106 specify a surface finish based on the manufacturing method used for creating each segmented wax model.

In one embodiment, based on the required level of surface finish, AI model 106 calculates how much material will be removed so that while manufacturing the segmented wax model, the 3D model will be modified with the appropriate tolerance limit.

Referring again to FIG. 3, investment casting facilitator 102 includes robotic controller engine 303 configured to dynamically establish a production line using robots 104 for assembling segmented wax models into a complete three-dimensional wax model of the object for investment casting taking into consideration the manufacturing process(es) to create the identified segmented wax models, tolerance limits for each segmented wax models, the determined positions and dimensions of the identified openings, excess material, if any, identified as coming out when the segmented wax models are joined, amount of surface finish and amount of material removal/insertion in the segmented wax models, etc.

In one embodiment, robotic controller engine 303 issues instructions for robots 104 to assemble the segmented wax models into a complete three-dimensional wax model of the object for investment casting. In one embodiment, such instructions are issued to base controller 203 and/or payload controller 212 of robots 104 to assemble two or more segmented wax models into a larger wax model, including a complete, complex, large three-dimensional wax model of an object.

As previously discussed, base controller 203 of robot 104 generates and distributes the appropriate command signals that cause other processing modules and units on robot 104 to start carrying out the requested job assignment (e.g., assembling segmented wax models). So, for example, when the received job assignment requires that robot 104 drive itself to a certain part chamber (e.g., part chamber that contains a designated segmented wax model) at a certain location in the physical environment, it is base controller 203 that generates the command signal that causes onboard navigation system 204 to start driving robot 104 to the specified destination. Base controller 203 also provides an activation signal for payload 202, if necessary, to cause payload 202 to perform a particular operation (e.g., pick designated segmented wax model from designated part chamber) at the specified job location.

Furthermore, in one embodiment, payload 202 includes robotic arms 215 configured to pick segmented wax models from part chambers in an array of part chambers forming the assembling floor of industrial facility 101. A “robotic arm 215,” as used herein, is a type of mechanical arm that is programmable with similar functions to a human arm. In one embodiment, robotic arms 215 are programmed via commands received by base controller 203 and/or payload controller 212 via investment casting facilitator 102. Furthermore, in one embodiment, with the use of robotic arm 215, robot 104 is able to assemble two or more segmented wax models into a larger wax model, including a complete, complex, large three-dimensional wax model of an object.

In one embodiment, robots 104 are controlled by robotic controller engine 303 to precisely control the assembling of the segmented wax models into a complete, complex, large three-dimensional wax model of the object.

In one embodiment, robots 104 implement quality control to verify the correct alignment and positioning of each segmented wax model being assembled into a complete, complex, large three-dimensional wax model of the object.

In one embodiment, sensors are utilized in industrial facility 101 to provide a feedback mechanism to ensure the accuracy and quality of each task performed by robots 104.

In one embodiment, robots 104 are configured to perform polishing for refining the surface finish of the wax models using robotic arms 215.

In one embodiment, industrial facility 101 includes quality control stations that are incorporated into the production line to inspect and assess the wax models for dimensional accuracy and surface finish.

In one embodiment, robots 104 perform a final polishing step using robotic arms 215 to ensure that the complete, complex, large three-dimensional wax model of the object has a smooth and uniform surface finish.

In this manner, complex three-dimensional wax models may be created for investment casting with less defects than creating such wax models using single injection molding.

A further description of these and other features is provided below in connection with the discussion of the method for creating complex three-dimensional wax models for investment casting.

Prior to the discussion of the method for creating complex three-dimensional wax models for investment casting, a description of the hardware configuration of investment casting facilitator 102 (FIG. 1) is provided below in connection with FIG. 5.

Referring now to FIG. 5, in conjunction with FIG. 1, FIG. 5 illustrates an embodiment of the present disclosure of the hardware configuration of investment casting facilitator 102 which is representative of a hardware environment for practicing the present disclosure.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 500 contains an example of an environment for the execution of at least some of the computer code (stored in block 501) involved in performing the inventive methods, such as creating complex three-dimensional wax models for investment casting. In addition to block 501, computing environment 500 includes, for example, investment casting facilitator 102, network 103, such as a wide area network (WAN), end user device (EUD) 502, remote server 503, public cloud 504, and private cloud 505. In this embodiment, investment casting facilitator 102 includes processor set 506 (including processing circuitry 507 and cache 508), communication fabric 509, volatile memory 510, persistent storage 511 (including operating system 512 and block 501, as identified above), peripheral device set 513 (including user interface (UI) device set 514, storage 515, and Internet of Things (IoT) sensor set 516), and network module 517. Remote server 503 includes remote database 518. Public cloud 504 includes gateway 519, cloud orchestration module 520, host physical machine set 521, virtual machine set 522, and container set 523.

Investment casting facilitator 102 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 518. As is well understood in the art of computer technology, and depending upon the technology, performance of a computer-implemented method may be distributed among multiple computers and/or between multiple locations. On the other hand, in this presentation of computing environment 500, detailed discussion is focused on a single computer, specifically investment casting facilitator 102, to keep the presentation as simple as possible. Investment casting facilitator 102 may be located in a cloud, even though it is not shown in a cloud in FIG. 5. On the other hand, investment casting facilitator 102 is not required to be in a cloud except to any extent as may be affirmatively indicated.

Processor set 506 includes one, or more, computer processors of any type now known or to be developed in the future. Processing circuitry 507 may be distributed over multiple packages, for example, multiple, coordinated integrated circuit chips. Processing circuitry 507 may implement multiple processor threads and/or multiple processor cores. Cache 508 is memory that is located in the processor chip package(s) and is typically used for data or code that should be available for rapid access by the threads or cores running on processor set 506. Cache memories are typically organized into multiple levels depending upon relative proximity to the processing circuitry. Alternatively, some, or all, of the cache for the processor set may be located “off chip.” In some computing environments, processor set 606 may be designed for working with qubits and performing quantum computing.

Computer readable program instructions are typically loaded onto investment casting facilitator 102 to cause a series of operational steps to be performed by processor set 506 of investment casting facilitator 102 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 508 and the other storage media discussed below. The program instructions, and associated data, are accessed by processor set 506 to control and direct performance of the inventive methods. In computing environment 500, at least some of the instructions for performing the inventive methods may be stored in block 501 in persistent storage 511.

Communication fabric 509 is the signal conduction paths that allow the various components of investment casting facilitator 102 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 510 is any type of volatile memory now known or to be developed in the future. Examples include dynamic type random access memory (RAM) or static type RAM. Typically, the volatile memory is characterized by random access, but this is not required unless affirmatively indicated. In investment casting facilitator 102, the volatile memory 510 is located in a single package and is internal to investment casting facilitator 102, but, alternatively or additionally, the volatile memory may be distributed over multiple packages and/or located externally with respect to investment casting facilitator 102.

Persistent Storage 511 is any form of non-volatile storage for computers that is now known or to be developed in the future. The non-volatility of this storage means that the stored data is maintained regardless of whether power is being supplied to investment casting facilitator 102 and/or directly to persistent storage 511. Persistent storage 511 may be a read only memory (ROM), but typically at least a portion of the persistent storage allows writing of data, deletion of data and re-writing of data. Some familiar forms of persistent storage include magnetic disks and solid state storage devices. Operating system 512 may take several forms, such as various known proprietary operating systems or open source Portable Operating System Interface type operating systems that employ a kernel. The code included in block 501 typically includes at least some of the computer code involved in performing the inventive methods.

Peripheral device set 513 includes the set of peripheral devices of investment casting facilitator 102. Data communication connections between the peripheral devices and the other components of investment casting facilitator 102 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 514 may include components such as a display screen, speaker, microphone, wearable devices (such as goggles and smart watches), keyboard, mouse, printer, touchpad, game controllers, and haptic devices. Storage 515 is external storage, such as an external hard drive, or insertable storage, such as an SD card. Storage 515 may be persistent and/or volatile. In some embodiments, storage 515 may take the form of a quantum computing storage device for storing data in the form of qubits. In embodiments where investment casting facilitator 102 is required to have a large amount of storage (for example, where investment casting facilitator 102 locally stores and manages a large database) then this storage may be provided by peripheral storage devices designed for storing very large amounts of data, such as a storage area network (SAN) that is shared by multiple, geographically distributed computers. IoT sensor set 516 is made up of sensors that can be used in Internet of Things applications. For example, one sensor may be a thermometer and another sensor may be a motion detector.

Network module 517 is the collection of computer software, hardware, and firmware that allows investment casting facilitator 102 to communicate with other computers through WAN 103. Network module 517 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 517 are performed on the same physical hardware device. In other embodiments (for example, embodiments that utilize software-defined networking (SDN)), the control functions and the forwarding functions of network module 517 are performed on physically separate devices, such that the control functions manage several different network hardware devices. Computer readable program instructions for performing the inventive methods can typically be downloaded to investment casting facilitator 102 from an external computer or external storage device through a network adapter card or network interface included in network module 517.

WAN 103 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 502 is any computer system that is used and controlled by an end user (for example, a customer of an enterprise that operates investment casting facilitator 102), and may take any of the forms discussed above in connection with investment casting facilitator 102. EUD 502 typically receives helpful and useful data from the operations of investment casting facilitator 102. For example, in a hypothetical case where investment casting facilitator 102 is designed to provide a recommendation to an end user, this recommendation would typically be communicated from network module 517 of investment casting facilitator 102 through WAN 103 to EUD 502. In this way, EUD 502 can display, or otherwise present, the recommendation to an end user. In some embodiments, EUD 502 may be a client device, such as thin client, heavy client, mainframe computer, desktop computer and so on.

Remote server 503 is any computer system that serves at least some data and/or functionality to investment casting facilitator 102. Remote server 503 may be controlled and used by the same entity that operates investment casting facilitator 102. Remote server 503 represents the machine(s) that collect and store helpful and useful data for use by other computers, such as investment casting facilitator 102. For example, in a hypothetical case where investment casting facilitator 102 is designed and programmed to provide a recommendation based on historical data, then this historical data may be provided to investment casting facilitator 102 from remote database 518 of remote server 503.

Public cloud 504 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 504 is performed by the computer hardware and/or software of cloud orchestration module 520. The computing resources provided by public cloud 504 are typically implemented by virtual computing environments that run on various computers making up the computers of host physical machine set 521, which is the universe of physical computers in and/or available to public cloud 504. The virtual computing environments (VCEs) typically take the form of virtual machines from virtual machine set 522 and/or containers from container set 523. It is understood that these VCEs may be stored as images and may be transferred among and between the various physical machine hosts, either as images or after instantiation of the VCE. Cloud orchestration module 520 manages the transfer and storage of images, deploys new instantiations of VCEs and manages active instantiations of VCE deployments. Gateway 519 is the collection of computer software, hardware, and firmware that allows public cloud 504 to communicate through WAN 103.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 505 is similar to public cloud 504, except that the computing resources are only available for use by a single enterprise. While private cloud 505 is depicted as being in communication with WAN 103 in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 504 and private cloud 505 are both part of a larger hybrid cloud.

Block 501 further includes the software components discussed above in connection with FIGS. 3-4 to create complex three-dimensional wax models for investment casting. In one embodiment, such components may be implemented in hardware. The functions discussed above performed by such components are not generic computer functions. As a result, investment casting facilitator 102 is a particular machine that is the result of implementing specific, non-generic computer functions.

In one embodiment, the functionality of such software components of investment casting facilitator 102, including the functionality for creating complex three-dimensional wax models for investment casting, may be embodied in an application specific integrated circuit.

As stated above, investment casting, also known as precision casting or lost-wax casting, is a manufacturing process used to create complex and intricate metal parts with a high degree of accuracy and detail. Investment casting is known for its ability to produce parts with intricate details and fine surface finishes. It is often used in industries, such as aerospace, automotive, jewelry, and art casting, where high precision and quality are essential. The process of investment casting includes various steps, such as pattern creation. A wax or similar material is used to create a pattern or replica of the desired part. This wax pattern or model is typically slightly oversized to account for shrinkage during the casting process. Next, multiple wax patterns are attached to a central wax gating system thereby creating a cluster of patterns that resemble a tree. This assembly is known as the “tree” or “sprue.” The wax tree is then coated with a ceramic material, which forms a hard shell around the patterns. This shell is called the “investment.” The investment is heated in an oven or autoclave, causing the wax to melt and run out, leaving behind a cavity in the shape of the desired part within the ceramic mold. The ceramic mold is fired at high temperatures to harden it and remove any remaining traces of wax. This creates a robust and heat-resistant mold. Molten metal, often aluminium, brass, bronze, or stainless steel, is then poured into the preheated mold. The metal fills the cavity and takes on the exact shape of the wax pattern. The metal cools and solidifies within the mold, forming the final part. Once the metal has solidified and cooled, the ceramic shell is broken and removed, revealing the cast metal part. The cast part may require additional machining, grinding, and other post-processing steps to achieve the desired surface finish and dimensional accuracy. Investment casting offers several advantages, making it a preferred choice for manufacturing complex parts with high precision and intricate details. Some of the key advantages of investment casting include the ability to create parts with highly complex and intricate shapes, including internal cavities, thin walls, and fine details that are difficult to achieve using other manufacturing methods. Furthermore, the process offers excellent dimensional accuracy and tight tolerances, reducing the need for additional machining and finishing, which can save time and costs. Other advantages of investment casting include the ability to product parts with a smooth and fine surface finish, reducing the need for extensive post-processing and achieving a high-quality appearance. Furthermore, the method minimizes material waste because only the exact amount of metal required for the part is used, and the wax patterns can be reused for multiple castings. Additionally, since investment casting produces parts with tight tolerances, less machining is usually needed, saving time and reducing material loss. Unfortunately, the manufacturing of complex, large three-dimensional objects with a high-quality surface finish presents a challenge for investment casting when creating exact wax patterns or models. Such wax models are often created using single injection molding, which results in defects in the wax models.

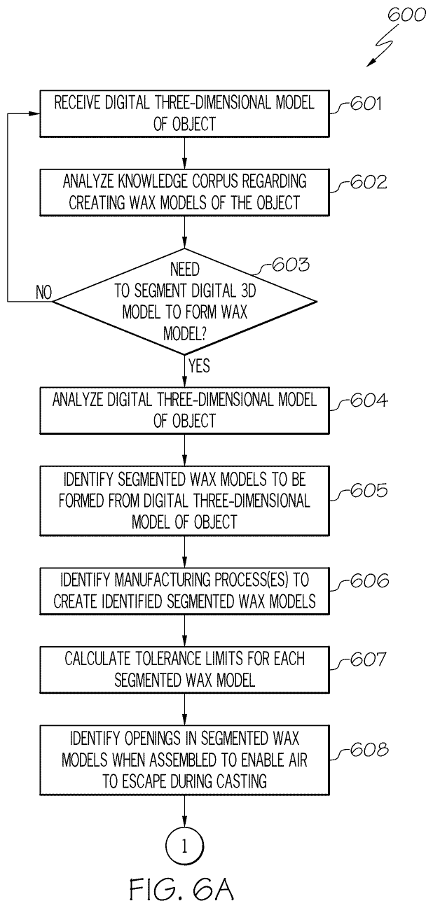

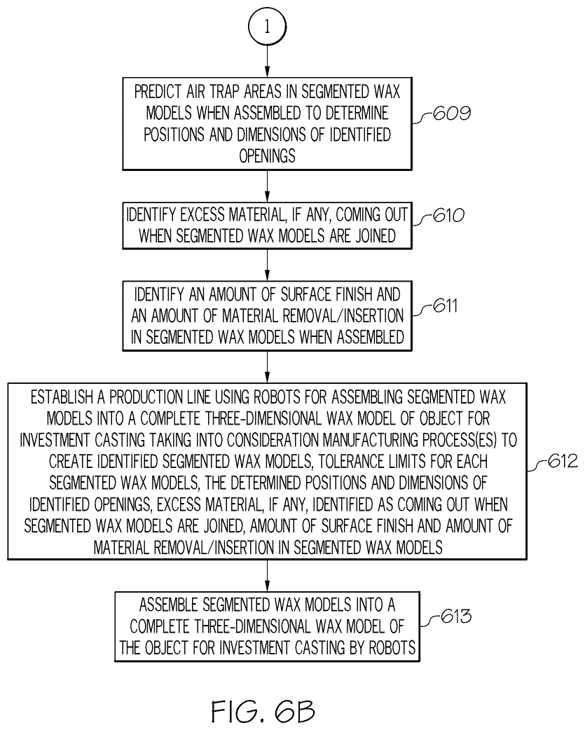

The embodiments of the present disclosure provide a means for creating more complex, accurate three-dimensional wax models than previously created using single injection molding as discussed below in connection with FIGS. 6A-6B.

FIGS. 6A-6B are a flowchart of a method 600 for creating complex three-dimensional wax models for investment casting in accordance with an embodiment of the present disclosure.

Referring to FIG. 6A, in conjunction with FIGS. 1-5, in operation 601, analyzing engine 301 of investment casting facilitator 102 receives a digital three-dimensional model of an object (e.g., transmission part, engine part, brake, bracket, housing, rod, gear, door handle, etc.). In one embodiment, the received digital three-dimensional model of an object is associated with an identifier (e.g., name of object), which identifies the object.

In operation 602, analyzing engine 301 of investment casting facilitator 102 analyzes knowledge corpus 105 regarding creating wax models of the object.

As discussed above, in one embodiment, knowledge corpus 105 is populated with a listing of three-dimensional objects for which the creation of wax models for investment casting using single injection modeling is difficult. In one embodiment, knowledge corpus 105 is populated by an expert.

In one embodiment, analyzing engine 301 determines if the creation of wax models for investment casting using single injection modeling is difficult for the object (e.g., brake pad) of the received digital three-dimensional model based on matching the identifier of the object with a listing of three-dimensional objects for which the creation of wax models for investment casting using single injection modeling is difficult.

In operation 603, upon receipt of the digital three-dimensional model of an object, analyzing engine 301 of investment casting facilitator 102 determines whether there is a need to segment the digital three-dimensional (3D) model to form a wax model based on the analysis of knowledge corpus 105.

As stated above, a segment, as used herein, refers to a portion or section. By segmenting the digital three-dimensional model, multiple segmented wax models are formed from the digital three-dimensional model of the object. A segmented wax model, as used herein, refers to a wax model of a portion or section of the object. In one embodiment, such segmented wax models may be assembled into a complete three-dimensional wax model of the object for investment casting with fewer defects than previously created using single injection molding.

In one embodiment, analyzing engine 301 determines whether there is a need to segment the received digital three-dimensional model to form a wax model based on the analysis of knowledge corpus 105 which involves determining if the creation of wax models for investment casting using single injection modeling is difficult for such an object (e.g., brake pad).

In one embodiment, knowledge corpus 105 contains information regarding the different types of three-dimensional model specifications and the types of defects in the wax model as illustrated in FIG. 4.

As shown in FIG. 4, a comparison is made between mesh model 401A of the three-dimensional model of the object and mesh model 401B of the wax model formed when created using single injection molding. In one embodiment, mesh models 401A, 401B are point cloud representations. As a result, in one embodiment, such a comparison corresponds to a point cloud comparison. A point cloud representation, as used herein, is a set of data points in a three-dimensional (3D) coordinate system (e.g., X, Y, and Z axes). A point cloud comparison, as used herein, refers to comparing the point cloud representations, such as the point cloud representations of mesh models 401A, 401B, to detect any changes which correspond to defects as discussed below.

In one embodiment, analyzing engine 301 creates such mesh models 401 using various software tools, which can include, but are not limited to, Blender, Autodesk Maya, 3ds Max®, etc.

In one embodiment, mesh model 401 is a collection of vertices, edges, and faces that together form a three-dimensional object. The vertices are the coordinates in three-dimensional space, the edges each connect two adjacent vertices, and the faces (also called polygons) enclose the edges to form the surface of the object.

In one embodiment, analyzing engine 301 detects defects 402 in the mesh model 401B of the wax model formed when created using single injection molding when there is a deviation between mesh models 401A, 401B, such as changes detected between the point cloud representations of mesh models 401A, 401B.

Manual annotation (see 403) may be utilized to highlight the defects with the wax models, where such defects are classified based on the types of defects.

Such information will be stored in knowledge corpus 105 and utilized to identify how different shapes, dimensions, etc. of the segmented wax models can avoid problems when assembled into the complete, complex, large three-dimensional wax model. In one embodiment, such information may be utilized by AI model 106, as discussed further below, to avoid problems when segmented wax models are assembled into the complete, complex, large three-dimensional wax model.

Based on such information in knowledge corpus 105, analyzing engine 301 determines whether there is a need to segment the received digital three-dimensional model to form a wax model based on the analysis of knowledge corpus 105 which involves determining if the creation of wax models for investment casting using single injection modeling is difficult for such an object (e.g., brake pad). Such difficulty is determined based on defects, such as defects 402 of FIG. 4 that were detected.

If there is no difficulty in creating a wax model for investment casting using single injection molding for such an object as determined from knowledge corpus 105, then a wax model for investment casting will be created for such an object using single injection molding. That is, if there is not a need to segment the received digital three-dimensional model of the object, then analyzing engine 301 of investment casting facilitator 102 proceeds to wait to receive the next digital three-dimensional model of an object in operation 601.

If, however, there is difficulty in creating a wax model for investment casting using single injection molding for such an object as determined from knowledge corpus 105, then analyzing engine 301 proceeds with identifying the segmented wax models to be formed from the digital three-dimensional model of the object.

That is, if there is a need to segment the digital three-dimensional model of the object to form the wax model, then, in operation 604, analyzing engine 301 of investment casting facilitator 102 analyzes the received digital three-dimensional model of an object (e.g., transmission part, engine part, brake, bracket, housing, rod, gear, door handle, etc.).

As discussed above, in one embodiment, analyzing engine 301 analyzes the digital three-dimensional model of the object by converting the digital three-dimensional model into a mesh model of granular sizes and dimensions. A mesh model, as used herein, is a collection of vertices, edges, and faces that together form a three-dimensional object. The vertices are the coordinates in three-dimensional space, the edges each connect two adjacent vertices, and the faces (also called polygons) enclose the edges to form the surface of the object.

In one embodiment, analyzing engine 301 creates a mesh model, such as a three-dimensional mesh model, from the digital three-dimensional model of the object using various software tools, which can include, but are not limited to, Blender, Autodesk Maya, 3ds Max®, etc.

In one embodiment, analyzing engine 301 creates a mesh model, such as a three-dimensional mesh model, from the object itself by utilizing three-dimensional scanning, which is a technique for converting a physical object into a three-dimensional mesh model. In one embodiment, a three-dimensional scanner is used to capture the surface of the object and create a digital mesh model.

In one embodiment, analyzing engine 301 identifies the geometry and dimensions of the different portions of the three-dimensional object from the three-dimensional mesh model. Analyzing engine 301 uses various software tools for such an analysis, which can include, but are not limited to, MeshInspector, 3ds Max®, MeshLab, etc.

In operation 605, analyzing engine 301 of investment casting facilitator 102 identifies the segmented wax models to be formed from the digital three-dimensional model of the object.

As stated above, in one embodiment, the segmented wax models are identified based on breaking down the three-dimensional object into multiple sections using the learned geometry and dimensions of the three-dimensional object, which are compared with previous sections of objects for which segmented wax models have been formed as identified in knowledge corpus 105.

Furthermore, as discussed above, knowledge corpus 105, as used herein, refers to a collection of data that contains information pertaining to identifying segmented wax models to be formed from a digital three-dimensional model of an object (e.g., transmission part, engine part, brake, bracket, housing, rod, gear, door handle, etc.) as well as information pertaining to assembling such segmented wax models into a complete, complex, large three-dimensional wax model. For example, such data may include which objects that accurate wax models can be created using single injection modeling and which objects that wax models cannot accurately be created using single injection modeling, sections of objects for which segmented wax models have been formed, the types of shapes and dimensions of three-dimensional objects where investment casting-based manufacturing will be difficult, manufacturing methods used for various types of segmented wax models (e.g., 3D printing, wax cutting), required surface finishes for various types of segmented wax models, amount of material removal for various assembled segmented wax models, alterations to be implemented in various assembled segmented wax models based on required allowances, etc.

In one embodiment, based on identifying sections of the three-dimensional object (e.g., brake pad) that have previously been segmented into segmented wax models from knowledge corpus 105, analyzing engine 301 proceeds with logically segmenting the digital three-dimensional model of the object. In one embodiment, analyzing engine 301 creates separate three-dimensional models or files for each segmented part preserving their alignment and assembly points. Analyzing engine 301 uses various software tools for creating separate three-dimensional models or files for each segmented part preserving their alignment and assembly points, which can include, but are not limited to, Alias®, Rhino, Blender®, etc.

In one embodiment, properties (e.g., geometry, dimensions, etc.) of such segmented wax models are obtained by analyzing engine 301, such as from the software tools used for creating separate three-dimensional models or files for each segmented wax model.

In one embodiment, once the digital three-dimensional model of the object is segmented, analyzing engine 301 allocates a sequence number to each segmented wax model in order of assembling thereby being able to assemble the segmented wax models into a complete three-dimensional wax model of the object for investment casting.

In operation 606, analyzing engine 301 of investment casting facilitator 102 identifies the manufacturing process(es) to create the identified segmented wax models.

As discussed above, in one embodiment, such manufacturing processes may be identified from knowledge corpus 105 or using AI model 106. As discussed above, in one embodiment, knowledge corpus 105 includes information pertaining to manufacturing methods used for various types of segmented wax models (e.g., 3D printing, wax cutting). Based on identifying the types of segmented wax models to be used (obtained from identifying the segmented wax models to be formed from the three-dimensional model of the object), such information may be utilized by analyzing engine 301 to identify the manufacturing processes to create the identified segmented wax models.

As also discussed above, AI model 106 refers to a program that has been trained on a set of data to recognize certain patterns or make certain decisions without further human intervention. Artificial intelligence models apply different algorithms to relevant data inputs to achieve the tasks, or output, they have been programmed for. That is, an AI model is defined by its ability to autonomously make decisions or predictions, rather than simulate human intelligence. Such decisions include the types of shapes and dimensions of the segmented wax models, manufacturing methods used for the segmented wax models (e.g., 3D printing, wax cutting), required surface finishes for the segmented wax models, amount of material removal for the assembled segmented wax models, alterations to be implemented in the assembled segmented wax models based on required allowances, calculating the necessary tolerance limits (e.g., tolerance limits for dimensions, surface roughness) for each individual segmented wax model, identifying the portions of the completed assembled wax model that are to be expanded into two or more separate sections which allow for the creation of two or more openings in the mold, predicting where air might become trapped within the mold to determine positions and dimensions of openings (openings identified to enable air to escape during casting) required in the molds for complete wax model creation, identifying sections of assembled wax models to create multiple mold openings to enable air to escape during casting, identifying excess material, if any, coming out when segmented wax models are joined, etc.

Furthermore, as stated above, investment casting facilitator 102 includes machine learning engine 302, which builds and trains an artificial intelligence model to make decision or predictions, such as the types of shapes and dimensions of the segmented wax models, manufacturing methods used for the segmented wax models (e.g., 3D printing, wax cutting), required surface finishes for the segmented wax models, amount of material removal for the assembled segmented wax models, alterations to be implemented in the assembled segmented wax models based on required allowances, calculating the necessary tolerance limits (e.g., tolerance limits for dimensions, surface roughness) for each individual segmented wax model, identifying the portions of the completed assembled wax model that are to be expanded into two or more separate sections which allow for the creation of two or more openings in the mold, predicting where air might become trapped within the mold to determine positions and dimensions of openings required in the molds for complete wax model creation, identifying sections of assembled wax models to create multiple mold openings to enable air to escape during casting, etc. Such decisions or predictions are based on a sample data set that includes the types of shapes and dimensions of the segmented wax models, manufacturing methods used for the segmented wax models (e.g., 3D printing, wax cutting), required surface finishes for the segmented wax models, amount of material removal for the assembled segmented wax models, alterations to be implemented in the assembled segmented wax models based on required allowances, the calculated necessary tolerance limits (e.g., tolerance limits for dimensions, surface roughness) for each individual segmented wax model, the portions of the completed assembled wax model that are to be expanded into two or more separate sections which allow for the creation of two or more openings in the mold, the predicted locations where air might become trapped within the mold to determine positions and dimensions of openings required in the molds for complete wax model creation, the sections of assembled wax models used to create multiple mold openings to enable air to escape during casting, etc. based on the properties of objects (e.g., geometry and dimensions of the different portions of the three-dimensional objects) and based on the properties (e.g., geometry, dimensions, etc.) of the identified segmented wax models.

In one embodiment, the sample data set discussed above may be stored in a data structure (e.g., table) residing within the storage device (e.g., storage device 511, 515) of investment casting facilitator 102. In one embodiment, such a data structure is populated by an expert.

Furthermore, in one embodiment, the sample data set discussed above is referred to herein as the “training data,” which is used by a machine learning algorithm to make predictions or decisions as discussed above. The algorithm iteratively makes predictions on the training data until the predictions achieve the desired accuracy as determined by an expert. Examples of such learning algorithms include nearest neighbor, Naïve Bayes, decision trees, linear regression, support vector machines, and neural networks.

Upon training artificial intelligence model 106 to make decision or predictions as discussed above based on the properties of objects (e.g., geometry and dimensions of the different portions of the three-dimensional objects) and based on the properties (e.g., geometry, dimensions, etc.) of the identified segmented wax models, the trained artificial intelligence model 106 generates such predictions for the object in question based on the properties of the object (e.g., geometry and dimensions of the different portions of the three-dimensional object) obtained from analyzing engine 301, such as based on analyzing the digital three-dimensional model of the object, as well as based on the properties of identified segmented wax models, which may be obtained from analyzing engine 301.

In one embodiment, AI model 106 generates manufacturing process(es) to create the identified segmented wax models based on the properties of the object and based on the properties of the identified segmented wax models.

Examples of such manufacturing processes can include, but are not limited to, wax injection modeling, wax 3D printing, CNC (computer numerical control) machining, polishing, assembling, quality evaluation, wax cutting, dipping on ceramic slurry, etc. to create wax patterns for each segmented part.

In one embodiment, such manufacturing processes ensure that the dimension and surface finish of each wax model meets the requirements for investment casting.

In operation 607, analyzing engine 301 of investment casting facilitator 102 calculates the tolerance limits for each segmented wax model. A tolerance limit, as used herein, is a measure used to ensure the uniformity or quality of the segmented wax model.

As discussed above, AI model 106 is trained to output the necessary tolerance limits for each segmented wax model to ensure accurate assembly and high-quality investment casting based on the properties of the object and the properties of the identified segmented wax models. In one embodiment, such an assessment performed by AI model 106 includes assessing factors, such as the manufacturing method's inherent accuracy, material properties, and the surface finish requirements.

In operation 608, analyzing engine 301 of investment casting facilitator 102 identifies the openings in the segmented wax models when they are assembled to enable air to escape during casting.

As discussed above, AI model 106 is trained to output the openings in the segmented wax models when they are assembled to enable air to escape during casting based on the properties of the object and the properties of the identified segmented wax models. For example, AI model 106 identifies the sections of the assembled wax models to create multiple mold openings to enable air to escape during casting based on the properties of the object and the properties of the identified segmented wax models. In one embodiment, such an assessment performed by AI model 106 includes ensuring that the expansion (completed assembled wax model is expanded into two or more separate sections) creates openings or channels in the model, which serve as pathways for air to escape during casting.

Referring now to FIG. 6B, in conjunction with FIGS. 1-5, in operation 609, analyzing engine 301 of investment casting facilitator 102 predicts air trap areas in the segmented wax models when they are assembled to determine positions and dimensions of the identified openings.

As discussed above, in one embodiment, analyzing engine 301 predicts air trap areas based on performing fluid dynamics simulations of the segmented wax models when they are assembled. Examples of software tools for implementing fluid dynamics simulations can include, but are not limited to, OpenFOAM®, Ansys® CFD simulation software, Autodesk® CFD software, etc.

Furthermore, as discussed above, AI model 106 is trained to predict where air might become trapped within the mold to determine the positions and dimensions of the openings (openings identified to enable air to escape during casting) required in the molds for complete wax model creation based on the properties of the object and the properties of the identified segmented wax models. In one embodiment, AI model 106 is trained, such as by machine learning engine 302, to recognize regions within the 3D model that are likely to lead to air trapping during the investment casting process. These could be areas with enclosed or hard-to-fill cavities. Furthermore, in one embodiment, AI model 106 is trained to expand the wax model, in two or more sides, so that the air trapped inside the mold can be released and aligned with the openings designed for air to escape.

In operation 610, analyzing engine 301 of investment casting facilitator 102 identifies excess material, if any, coming out when segmented wax models are joined.

As discussed above, AI model 106 is trained to predict any excess material coming out when segmented wax models are joined based on the properties of the object and the properties of the identified segmented wax models.

In situations in which excess material is predicted to come out when segmented wax models are joined, robots 104 will be employed to heat the surfaces of the segmented wax models prior to assembly. In one embodiment, such heating involves infrared or induction heating. Robots 104 may then apply controlled pressure to securely join the segmented wax models ensuring that excess wax does not escape.

In one embodiment, in the event that excess wax escapes from the assembled portion of the segmented wax models, robots 104 may be employed to perform polishing to remove such excess wax thereby enabling the assembled segmented wax models to be utilized in forming the complete three-dimensional wax model of the object for investment casting.

In operation 611, analyzing engine 301 of investment casting facilitator 102 identifies an amount of surface finish and an amount of material removal/insertion in the segmented wax models when assembled.

As discussed above, AI model 106 is trained to predict an amount of surface finish and an amount of material removal/insertion in the segmented wax models when assembled based on the properties of the object and the properties of the identified segmented wax models.

Furthermore, as discussed above, analyzing engine 301 identifies the amount of surface finish and an amount of material removal/insertion in the segmented wax models when assembled from knowledge corpus 105. For example, based on the properties (e.g., type of segmented wax model) of the identified segmented wax models, the amount of surface finish may be obtained from knowledge corpus 105, which stores the required surface finish for various types of segmented wax models. Furthermore, based on the properties (e.g., type of segmented wax model) of the segmented wax models, the amount of material removal/insertion in the segmented wax models when assembled may be obtained from knowledge corpus 105, which stores the amount of material removal for various assembled segmented wax models as well as alterations to be implemented in various assembled segmented wax models based on the required allowances (i.e., tolerances).

In one embodiment, knowledge corpus 105 stores the desired surface finish specification for the investment casting process based on the surface roughness, dimensional tolerances, and other quality requirements. Hence, analyzing engine 301, based on the surface roughness, dimensional tolerances, and other quality requirements of the segmented wax models, is able to identify the desired surface finish specification from knowledge corpus 105.

In one embodiment, knowledge corpus 105 and AI model 106 specify a surface finish based on the manufacturing method used for creating each segmented wax model.

In one embodiment, based on the required level of surface finish, AI model 106 calculates how much material will be removed so that while manufacturing the segmented wax model, the 3D model will be modified with the appropriate tolerance limit.

In operation 612, robotic controller engine 303 of investment casting facilitator 102 dynamically establishes a production line using robots 104 for assembling the segmented wax models into a complete three-dimensional wax model of the object for investment casting taking into consideration the manufacturing process(es) to create the identified segmented wax models, tolerance limits for each segmented wax models, the determined positions and dimensions of the identified openings, excess material, if any, identified as coming out when the segmented wax models are joined, amount of surface finish and amount of material removal/insertion in the segmented wax models, etc.

In one embodiment, robotic controller engine 303 issues instructions for robots 104 to assemble the segmented wax models into a complete three-dimensional wax model of the object for investment casting. In one embodiment, such instructions are issued to base controller 203 and/or payload controller 212 of robots 104 to assemble two or more segmented wax models into a larger wax model, including a complete, complex, large three-dimensional wax model of an object.

In operation 613, robots 104 assemble the segmented wax models into a complete three-dimensional wax model of the object for investment casting as programmed by robotic controller engine 303.

As previously discussed, base controller 203 generates and distributes the appropriate command signals that cause other processing modules and units on robot 104 to start carrying out the requested job assignment (e.g., assembling segmented wax models). So, for example, when the received job assignment requires that robot 104 drive itself to a certain part chamber (e.g., part chamber that contains a designated segmented wax model) at a certain location in the physical environment, it is base controller 203 that generates the command signal that causes onboard navigation system 204 to start driving robot 104 to the specified destination. Base controller 203 also provides an activation signal for payload 202, if necessary, to cause payload 202 to perform a particular operation (e.g., pick designated segmented wax model from designated part chamber) at the specified job location.

Furthermore, in one embodiment, payload 202 includes robotic arms 215 configured to pick segmented wax models from part chambers in an array of part chambers forming the assembling floor of industrial facility 101. A “robotic arm 215,” as used herein, is a type of mechanical arm that is programmable with similar functions to a human arm. In one embodiment, robotic arms 215 are programmed via commands received by base controller 203 and/or payload controller 212 via investment casting facilitator 102. Furthermore, in one embodiment, with the use of robotic arm 215, robot 104 is able to assemble two or more segmented wax models into a larger wax model, including a complete, complex, large three-dimensional wax model of an object.

In one embodiment, robots 104 are controlled by robotic controller engine 303 to precisely control the assembling of the segmented wax models into a complete, complex, large three-dimensional wax model of the object.

In one embodiment, robots 104 implement quality control to verify the correct alignment and positioning of each segmented wax model being assembled into a complete, complex, large three-dimensional wax model of the object.

In one embodiment, sensors are utilized in industrial facility 101 to provide a feedback mechanism to ensure the accuracy and quality of each task performed by robots 104.

In one embodiment, robots 104 are configured to perform polishing for refining the surface finish of the wax models using robotic arms 215.

In one embodiment, industrial facility 101 includes quality control stations that are incorporated into the production line to inspect and assess the wax models for dimensional accuracy and surface finish.

In one embodiment, robots 104 perform a final polishing step using robotic arms 215 to ensure that the complete, complex, large three-dimensional wax model of the object has a smooth and uniform surface finish.

In this manner, complex three-dimensional wax models may be created for investment casting with less defects than creating such wax models using single injection molding.

Furthermore, the principles of the present disclosure improve the technology or technical field involving investment casting.

As discussed above, investment casting, also known as precision casting or lost-wax casting, is a manufacturing process used to create complex and intricate metal parts with a high degree of accuracy and detail. Investment casting is known for its ability to produce parts with intricate details and fine surface finishes. It is often used in industries, such as aerospace, automotive, jewelry, and art casting, where high precision and quality are essential. The process of investment casting includes various steps, such as pattern creation. A wax or similar material is used to create a pattern or replica of the desired part. This wax pattern or model is typically slightly oversized to account for shrinkage during the casting process. Next, multiple wax patterns are attached to a central wax gating system thereby creating a cluster of patterns that resemble a tree. This assembly is known as the “tree” or “sprue.” The wax tree is then coated with a ceramic material, which forms a hard shell around the patterns. This shell is called the “investment.” The investment is heated in an oven or autoclave, causing the wax to melt and run out, leaving behind a cavity in the shape of the desired part within the ceramic mold. The ceramic mold is fired at high temperatures to harden it and remove any remaining traces of wax. This creates a robust and heat-resistant mold. Molten metal, often aluminium, brass, bronze, or stainless steel, is then poured into the preheated mold. The metal fills the cavity and takes on the exact shape of the wax pattern. The metal cools and solidifies within the mold, forming the final part. Once the metal has solidified and cooled, the ceramic shell is broken and removed, revealing the cast metal part. The cast part may require additional machining, grinding, and other post-processing steps to achieve the desired surface finish and dimensional accuracy. Investment casting offers several advantages, making it a preferred choice for manufacturing complex parts with high precision and intricate details. Some of the key advantages of investment casting include the ability to create parts with highly complex and intricate shapes, including internal cavities, thin walls, and fine details that are difficult to achieve using other manufacturing methods. Furthermore, the process offers excellent dimensional accuracy and tight tolerances, reducing the need for additional machining and finishing, which can save time and costs. Other advantages of investment casting include the ability to product parts with a smooth and fine surface finish, reducing the need for extensive post-processing and achieving a high-quality appearance. Furthermore, the method minimizes material waste because only the exact amount of metal required for the part is used, and the wax patterns can be reused for multiple castings. Additionally, since investment casting produces parts with tight tolerances, less machining is usually needed, saving time and reducing material loss. Unfortunately, the manufacturing of complex, large three-dimensional objects with a high-quality surface finish presents a challenge for investment casting when creating exact wax patterns or models. Such wax models are often created using single injection molding, which results in defects in the wax models.

Embodiments of the present disclosure improve such technology by analyzing a digital three-dimensional model of an object (e.g., transmission part, engine part, brake, bracket, housing, rod, gear, door handle, etc.). In one embodiment, the digital three-dimensional model of the object is analyzed by converting the digital three-dimensional model into a mesh model of granular sizes and dimensions, where the geometry and dimensions of the different portions of the three-dimensional object from the three-dimensional mesh model are identified. A mesh model, as used herein, is a collection of vertices, edges, and faces that together form a three-dimensional object. The vertices are the coordinates in three-dimensional space, the edges each connect two adjacent vertices, and the faces (also called polygons) enclose the edges to form the surface of the object. Segmented wax models to be formed from the digital three-dimensional model of the object are then identified. In one embodiment, the segmented wax models are identified based on breaking down the three-dimensional object into multiple sections using the learned geometry and dimensions of the three-dimensional object, which are compared with previous sections of objects for which segmented wax models have been formed as identified in a knowledge corpus. A production line using robots is then established for assembling the identified segmented wax models into a complete three-dimensional wax model of the object for investment casting. In one embodiment, the production line is dynamically established using robots for assembling segmented wax models into a complete three-dimensional wax model of the object for investment casting taking into consideration the manufacturing processes used to create the identified segmented wax models, tolerance limits for each segmented wax models, the determined positions and dimensions of identified openings, excess material, if any, identified as coming out when segmented wax models are joined, amount of surface finish and amount of material removal/insertion in the segmented wax models, etc. In this manner, complex three-dimensional wax models may be created for investment casting with less defects than creating such wax models using single injection molding. Furthermore, in this manner, there is an improvement in the technical field involving investment casting.

The technical solution provided by the present disclosure cannot be performed in the human mind or by a human using a pen and paper. That is, the technical solution provided by the present disclosure could not be accomplished in the human mind or by a human using a pen and paper in any reasonable amount of time and with any reasonable expectation of accuracy without the use of a computer.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A computer-implemented method for creating complex three-dimensional wax models for investment casting, the method comprising:
analyzing a digital three-dimensional model of an object;
identifying segmented wax models to be formed from the digital three-dimensional model of the object; and
establishing a production line using robots for assembling the identified segmented wax models into a complete three-dimensional wax model of the object for the investment casting.

2. The method as recited in claim 1 further comprising:
analyzing a knowledge corpus regarding creating wax models of the object, wherein the knowledge corpus comprises one or more of the following information selected from the group consisting of: which objects that accurate wax models can be created using single injection modeling, which objects that wax models cannot accurately be created using single injection modeling, sections of objects for which segmented wax models have been formed, types of shapes and dimensions of three-dimensional objects where investment casting-based manufacturing will be difficult, manufacturing methods used for various types of segmented wax models, required surface finishes for various types of segmented wax models, amount of material removal for various assembled segmented wax models, and alterations to be implemented in various assembled segmented wax models based on required allowances.

3. The method as recited in claim 1 further comprising:
identifying one or more manufacturing processes to create the identified segmented wax models; and
calculating tolerance limits for each identified segmented wax model.

4. The method as recited in claim 3 further comprising:
identifying openings in the identified segmented wax models when assembled to enable air to escape during casting; and
predicting air trap areas in the identified segmented wax models when assembled to determine positions and dimensions of the identified openings.

5. The method as recited in claim 4 further comprising:
identifying excess material, if any, coming out when the identified segmented wax models are joined;
identifying an amount of surface finish in the identified segmented wax models when assembled; and
identifying an amount of material removal or insertion in the identified segmented wax models when assembled.

6. The method as recited in claim 5 further comprising:
establishing the production line using robots for assembling the identified segmented wax models into the complete three-dimensional wax model of the object for the investment casting taking into consideration the identified one or more manufacturing processes to create the identified segmented wax models, the calculated tolerance limits for each identified segmented wax model, the identified openings in the identified segmented wax models when assembled to enable air to escape during casting, the predicted air trap areas in the identified segmented wax models when assembled to determine positions and dimensions of the identified openings, the identified excess material, if any, coming out when the identified segmented wax models are joined, the identified amount of surface finish in the identified segmented wax models when assembled, and the identified amount of material removal or insertion in the identified segmented wax models when assembled.

7. The method as recited in claim 1, wherein the digital three-dimensional model of the object is converted into a mesh model in order to analyze the digital three-dimensional model of the object.

8. A computer program product comprising:
a set of one or more computer-readable storage media; and
program instructions, collectively stored in the set of one or more computer-readable storage media, for causing a processor set to perform the following computer operations:
analyzing a digital three-dimensional model of an object;
identifying segmented wax models to be formed from the digital three-dimensional model of the object; and
establishing a production line using robots for assembling the identified segmented wax models into a complete three-dimensional wax model of the object for the investment casting.

9. The computer program product as recited in claim 8, wherein the program instructions cause the processer set to perform the following computer operation:
analyzing a knowledge corpus regarding creating wax models of the object, wherein the knowledge corpus comprises one or more of the following information selected from the group consisting of: which objects that accurate wax models can be created using single injection modeling, which objects that wax models cannot accurately be created using single injection modeling, sections of objects for which segmented wax models have been formed, types of shapes and dimensions of three-dimensional objects where investment casting-based manufacturing will be difficult, manufacturing methods used for various types of segmented wax models, required surface finishes for various types of segmented wax models, amount of material removal for various assembled segmented wax models, and alterations to be implemented in various assembled segmented wax models based on required allowances.

10. The computer program product as recited in claim 8, wherein the program instructions cause the processer set to perform the following computer operations:
identifying one or more manufacturing processes to create the identified segmented wax models; and
calculating tolerance limits for each identified segmented wax model.

11. The computer program product as recited in claim 10, wherein the program instructions cause the processer set to perform the following computer operations:
identifying openings in the identified segmented wax models when assembled to enable air to escape during casting; and
predicting air trap areas in the identified segmented wax models when assembled to determine positions and dimensions of the identified openings.

12. The computer program product as recited in claim 11, wherein the program instructions cause the processer set to perform the following computer operations:
identifying excess material, if any, coming out when the identified segmented wax models are joined;
identifying an amount of surface finish in the identified segmented wax models when assembled; and
identifying an amount of material removal or insertion in the identified segmented wax models when assembled.

13. The computer program product as recited in claim 12, wherein the program instructions cause the processer set to perform the following computer operation:
establishing the production line using robots for assembling the identified segmented wax models into the complete three-dimensional wax model of the object for the investment casting taking into consideration the identified one or more manufacturing processes to create the identified segmented wax models, the calculated tolerance limits for each identified segmented wax model, the identified openings in the identified segmented wax models when assembled to enable air to escape during casting, the predicted air trap areas in the identified segmented wax models when assembled to determine positions and dimensions of the identified openings, the identified excess material, if any, coming out when the identified segmented wax models are joined, the identified amount of surface finish in the identified segmented wax models when assembled, and the identified amount of material removal or insertion in the identified segmented wax models when assembled.

14. The computer program product as recited in claim 8, wherein the digital three-dimensional model of the object is converted into a mesh model in order to analyze the digital three-dimensional model of the object.

15. A system, comprising:
a memory for storing a computer program for creating complex three-dimensional wax models for investment casting; and
a processor connected to the memory, wherein the processor is configured to execute program instructions of the computer program comprising:
analyzing a digital three-dimensional model of an object;
identifying segmented wax models to be formed from the digital three-dimensional model of the object; and
establishing a production line using robots for assembling the identified segmented wax models into a complete three-dimensional wax model of the object for the investment casting.

16. The system as recited in claim 15, wherein the program instructions of the computer program further comprise:
analyzing a knowledge corpus regarding creating wax models of the object, wherein the knowledge corpus comprises one or more of the following information selected from the group consisting of: which objects that accurate wax models can be created using single injection modeling, which objects that wax models cannot accurately be created using single injection modeling, sections of objects for which segmented wax models have been formed, types of shapes and dimensions of three-dimensional objects where investment casting-based manufacturing will be difficult, manufacturing methods used for various types of segmented wax models, required surface finishes for various types of segmented wax models, amount of material removal for various assembled segmented wax models, and alterations to be implemented in various assembled segmented wax models based on required allowances.

17. The system as recited in claim 15, wherein the program instructions of the computer program further comprise:
identifying one or more manufacturing processes to create the identified segmented wax models; and
calculating tolerance limits for each identified segmented wax model.

18. The system as recited in claim 17, wherein the program instructions of the computer program further comprise:
identifying openings in the identified segmented wax models when assembled to enable air to escape during casting; and
predicting air trap areas in the identified segmented wax models when assembled to determine positions and dimensions of the identified openings.

19. The system as recited in claim 18, wherein the program instructions of the computer program further comprise:
identifying excess material, if any, coming out when the identified segmented wax models are joined;
identifying an amount of surface finish in the identified segmented wax models when assembled; and
identifying an amount of material removal or insertion in the identified segmented wax models when assembled.

20. The system as recited in claim 19, wherein the program instructions of the computer program further comprise:
establishing the production line using robots for assembling the identified segmented wax models into the complete three-dimensional wax model of the object for the investment casting taking into consideration the identified one or more manufacturing processes to create the identified segmented wax models, the calculated tolerance limits for each identified segmented wax model, the identified openings in the identified segmented wax models when assembled to enable air to escape during casting, the predicted air trap areas in the identified segmented wax models when assembled to determine positions and dimensions of the identified openings, the identified excess material, if any, coming out when the identified segmented wax models are joined, the identified amount of surface finish in the identified segmented wax models when assembled, and the identified amount of material removal or insertion in the identified segmented wax models when assembled.
